(19) United States
(12) Patent Application Publication
(10) Pub. No.: US 2024/0222475 A1
(43) Pub. Date: Jul. 4, 2024

(54) TECHNOLOGIES FOR HIGH-PERFORMANCE MAGNETOELECTRIC SPIN-ORBIT LOGIC

(71) Applicant: Intel Corporation, Santa Clara, CA (US)

(72) Inventors: Punyashloka Debashis, Hillsboro, OR (US); Dmitri Evgenievich Nikonov, Beaverton, OR (US); Ian Alexander Young, Olympia, WA (US); John J. Plombon, Portland, OR (US); Scott B. Clendenning, Portland, OR (US); Mahendra DC, Portland, OR (US)

(73) Assignee: Intel Corporation, Santa Clara, CA (US)

(21) Appl. No.: 18/148,617

(22) Filed: Dec. 30, 2022

(51) Int. Cl. H01L 29/66; H01F 10/12; H01F 10/193; H01F 10/32; H10N 52/01

(52) U.S. Cl. CPC H01L 29/66984; H01F 10/12; H01F 10/1933; H01F 10/329; H10N 52/01

(57) ABSTRACT

Technologies for high-performance magnetoelectric spin-orbit (MESO) logic structures are disclosed. In the illustrative embodiment, the spin-orbit coupling layer of a MESO logic structure is a high-entropy perovskite. The use of a high-entropy perovskite provides versatility through tunability, as there is a wide range of possible combinations. Additional layers of the MESO logic structure may also be perovskites, such as the magnetoelectric layer and ferromagnetic layer. The various perovskite layers may be epitaxially compatible, allowing for growth of high-quality layers.

### BACKGROUND

For decades, most electronics have relied on the use of complementary metal-oxide-semiconductor (CMOS) transistors. However, the principles of CMOS operation, involving a switchable semiconductor conductance controlled by an insulating gate, have remained largely unchanged, even as transistors are miniaturized to sizes of 10 nanometers. One possible change from the CMOS paradigm is spintronic logic that operates via spin-orbit transduction combined with magnetoelectric switching. Spintronic logic can potentially provide lower switching energy, lower switching voltage, and higher density. Additionally, spintronic logic can be non-volatile, enabling low standby power.

### BRIEF DESCRIPTION OF THE DRAWINGS

FIG. 1 is an isometric view of one embodiment of magnetoelectric spin-orbit (MESO) logic structure.

FIG. 2 is a top-down view of the MESO logic structure of FIG. 1.

FIG. 3 is a cross-sectional view of the MESO logic structure of FIG. 1.

FIG. 4 is a cross-sectional view of the MESO logic structure of FIG. 1.

FIG. 5 is a cross-sectional view of the MESO logic structure of FIG. 1.

FIG. 6 is a plot showing spin-to-charge conversion efficiency as a function of resistivity.

FIG. 7 is a simplified circuit diagram of one embodiment including a magnetoelectric spin-orbit (MESO) majority gate.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIGS. 10A-10D are perspective views of example planar, gate-all-around, and stacked gate-all-around transistors.

FIG. 11 is a cross-sectional side view of an integrated circuit device assembly that may include a microelectronic assembly, in accordance with any of the embodiments disclosed herein.

FIG. 12 is a block diagram of an example electrical device that may include a microelectronic assembly, in accordance with any of the embodiments disclosed herein.

### DETAILED DESCRIPTION

In various embodiments disclosed herein, magnetoelectric spin-orbit (MESO) logic structures can be formed by connecting a differential input across a magnetoelectric layer. In the illustrative embodiment, the electric and magnetic polarization of the magnetoelectric multiferroic layer is determined by the direction of the electric field between the two inputs. The magnetoelectric multiferroic layer is coupled to a ferromagnetic layer, and the magnetic polarization of the ferromagnetic layer follows the direction of the magnetic polarization of the magnetoelectric multiferroic layer. Current that passes through the ferromagnetic layer becomes spin polarized. When the spin-polarized current passes through a spin-orbit-coupling material, a voltage differential is created at an output of the MESO logic structure. Such an approach can be used to create general logic gates, such as majority gates.

One important performance metric for MESO logic structures is the spin-to-charge conversion of the spin-orbit coupling layer and the resistivity of the spin-orbit coupling layer. Both a higher spin-to-charge conversion and a higher resistivity generally improve the performance of a MESO logic structure. One possible class of materials disclosed herein for the spin-orbit coupling layer is perovskites and, in particular, high-entropy perovskites. A perovskite material is any crystalline material with a crystal structure similar to calcium titanate (CaTiO₃), typically with the chemical formula of ABX₃, where A is one element, B is a second element, and X is a third element. A high-entropy material is one in which, e.g., five or more principal elements. For example, a high-entropy alloy has equal or relatively large proportions of five or more elements. A high-entropy oxide has five or more principal metal cations and has a single-phase crystal structure.

In a high entropy perovskite, the B site of the cubic perovskite lattice can be different elements as different lattice sites, each producing a slightly different tilt of the oxygen octahedron in that lattice site. High-entropy perovskites are highly versatile material systems with different combinations of elements for the B site, providing a wide parameter space for the choice of a high-entropy perovskite material.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

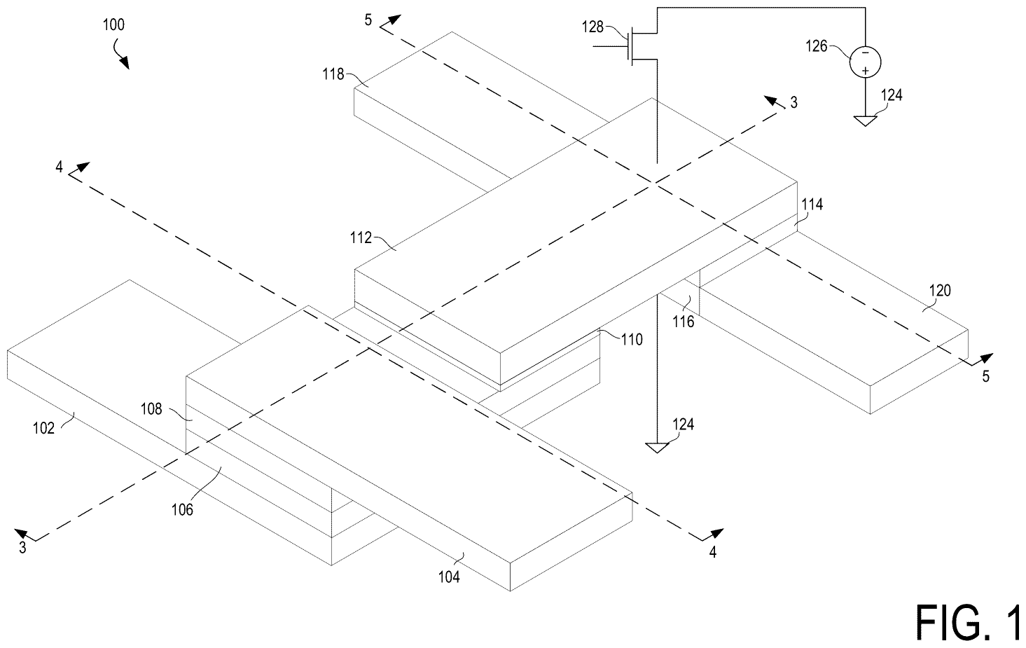

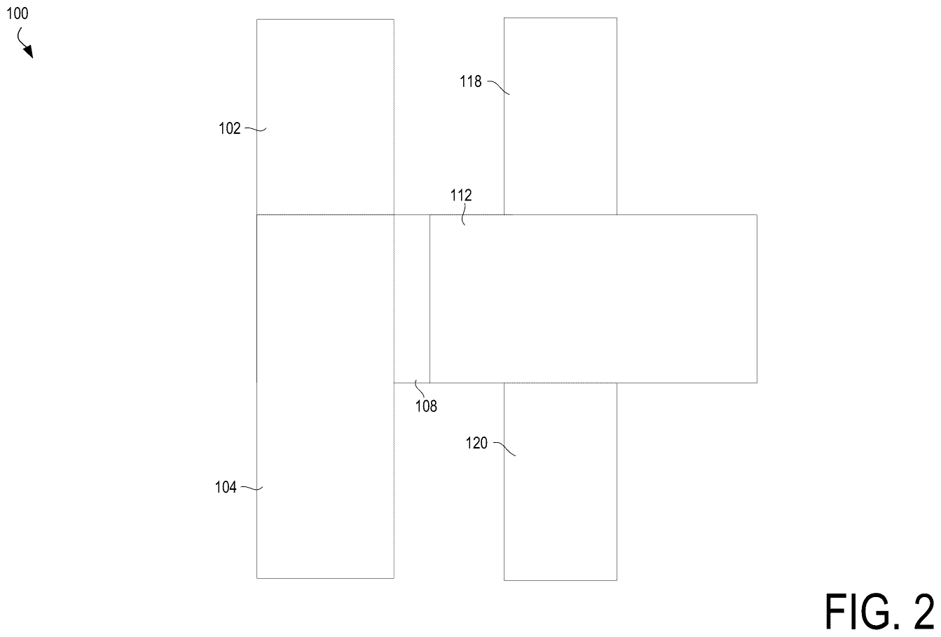

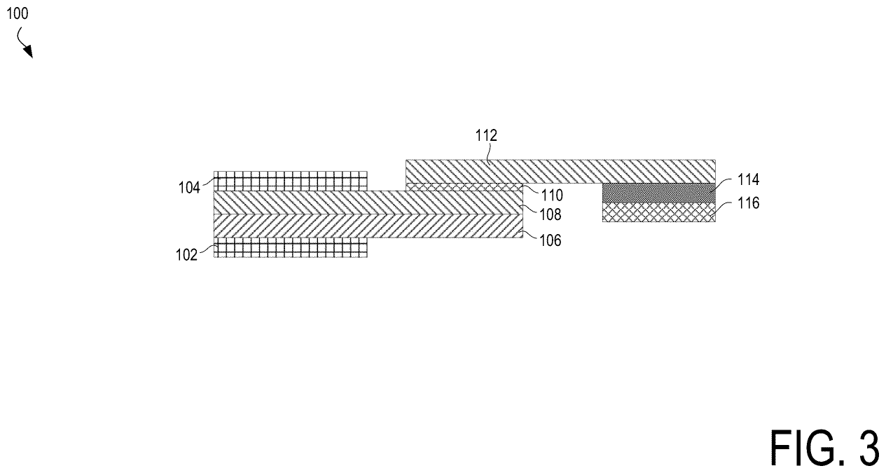

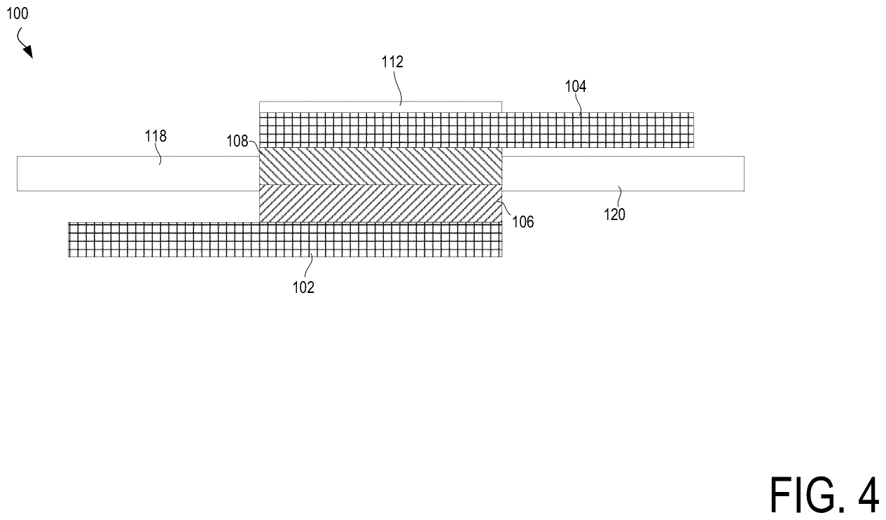

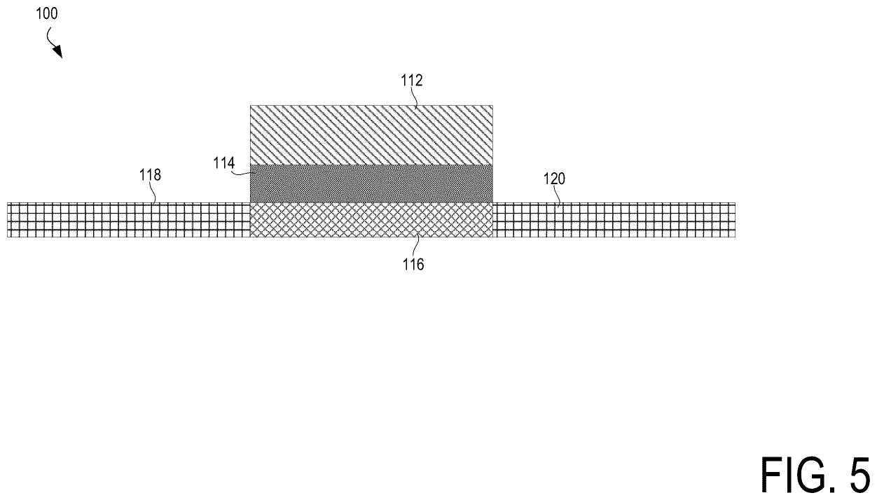

Referring now to FIGS. 1-5, in one embodiment, MESO logic structure 100 has a differential input formed by a bottom input electrode 102 and a top input electrode 104. FIG. 2 shows a top-down view of the MESO logic structure 100, and FIGS. 3-5 show various cross-sections of the MESO logic structure 100. A magnetoelectric multiferroic layer 106 is located on the bottom input electrode 102. A ferromagnetic layer 108 is located on the magnetoelectric multiferroic layer 106. The top input electrode 104 is located on the ferromagnetic layer 108.

In the illustrative embodiment, an electrically-insulating layer 110 is located on one end of the ferromagnetic layer 108, as shown in FIG. 1. Another ferromagnetic layer 112 is located on the insulating layer 110. The ferromagnetic layer 112 couples to the ferromagnetic layer 108 to function as one ferromagnet that switches coherently.

A spin injection/coherent layer 114 (in which it is easy for spin to travel) is adjacent a bottom side of the ferromagnetic layer 112, and a spin-orbit coupling stack 116 is adjacent a bottom side of the spin injection layer 114. A differential output is formed by a first output electrode 118 adjacent one side of the spin-orbit coupling stack 116 and a second output electrode 120 adjacent the opposite side of the spin-orbit coupling stack 116. The spin-orbit coupling stack 116 is connected to a ground 124. The insulating layer 110 electrically isolates the input electrodes 102, 104 from the spin-orbit layer 116 and the output electrodes 118, 120.

Current can be injected through the ferromagnetic layer 112, the spin injection layer 114, and the spin-orbit coupling stack 116 by turning on a transistor 128 connected to a voltage source 126 and the ferromagnetic layer 112. In the illustrative embodiment, the transistor 128 and voltage source 126 act as a clock.

In use, in the illustrative embodiment, the input electrodes 102, 104 are differential inputs. For example, if input electrode 102 is +1 volts, input electrode 104 is −1 volts. The input electrodes 102, 104 polarize the magnetoelectric layer 106. In the illustrative embodiment, the magnetoelectric layer 106 is ferroelectric and ferromagnetic. As such, as the input electrodes 102, 104 cause an electric field across the magnetoelectric layer 106, the magnetoelectric layer 106 becomes electrically polarized and magnetically polarized in a direction that depends on the voltages of the input electrodes 102, 104. The magnetization of the ferromagnetic layer 108 aligns with the magnetic field of the magnetoelectric layer 106 below it. As such, the state of the input electrodes 102, 104 determines the direction of the magnetic field of the ferromagnetic layer 108. As the ferromagnetic layer 112 is coupled to the ferromagnetic layer 108, the state of the input electrodes 102, 104 also determines the direction of the magnetic field of the ferromagnetic layer 112.

When the transistor 128 is turned on, electrons flow through the ferromagnetic layer 112. The electrons are polarized in a direction that depends on the state of the ferromagnetic layer 112 (and, therefore, in a direction that depends on the state of the input electrodes 102, 104). The polarized electrons pass through the spin injection layer 114 and the spin-orbit coupling stack 116. In the spin-orbit coupling stack 116, a force is applied to the electrons depending on their polarization due to spin-orbit coupling, creating a voltage between the two sides of the spin-orbit coupling stack 116 to which the output electrodes 118, 120 are connected.

Overall, the voltage state of the input electrodes 102, 104 is converted to the polarization and magnetization of the magnetoelectric layer 106 and the magnetization of the ferromagnetic layers 108, 112. The spin-orbit effect in the spin-orbit coupling stack 116 then maps the magnetization the ferromagnetic layer 112 back to voltage on the output electrodes 118, 120.

The input electrodes 102, 104 and/or output electrodes 118, 120 may be any suitable conductive material that can directly or indirectly interface with the other layers of the MESO logic structure 100. In the illustrative embodiment, the input electrodes 102, 104 and/or output electrodes 118, 120 are copper. In some embodiments, the input electrodes 102, 104 and/or output electrodes 118, 120 may be conductive perovskites

The magnetoelectric layer 106 may be any suitable magnetoelectric material. In the illustrative embodiment, the magnetoelectric layer 106 is bismuth ferrite (BiFeO₃). In some embodiments, the magnetoelectric layer 106 may be bismuth ferrite doped with lanthanum, which may reduce the coercive voltage. In some embodiments, the magnetoelectric layer 106 may be made of a material that is magnetoelectric at cryogenic temperatures. In some embodiments, the magnetoelectric layer 106 may be ferroelectric. In other embodiments, the magnetoelectric layer 106 may not be ferroelectric.

The ferromagnetic layers 108 and/or 112 may be any suitable ferromagnetic material. In the illustrative embodiment, the ferromagnetic layers 108 and/or 112 are ferromagnetic oxides such as Sr₂CrReO₆ (SCRO), Sr₂FeMoO₆ (SFMO). La_{0.7}Sr_{0.3}MnO₃ (LSMO), and/or Fe₃O₄, Ba_{0.604}Sr_{0.396}Fe_{0.25}Mn_{0.75}O₃(BSFMO). In other embodiments, the ferromagnetic layers 108 and/or 112 may be another ferromagnetic material, such as CoFe.

The spin injection layer 114 may be used when the spin-orbit coupling stack 116 does not interface well with the ferromagnetic layer 112. In some embodiments, the spin injection layer 114 may be omitted. In embodiments with the spin injection layer 114, the spin injection layer 114 may be one or more of any suitable materials that can pass spin-polarized current and interface with both the ferromagnetic layer 112 and the spin-orbit coupling stack 116.

The spin-orbit coupling stack 116 may be any suitable material or combination of materials with a suitable spin-orbit coupling. The spin-orbit coupling stack 116 may be a single layer or may be a combination of two or more different layers, such as two or more alternating layers. In the illustrative embodiment, the spin-orbit coupling stack 116 is a high-entropy perovskite. For example, the spin-orbit coupling stack 116 may be Sr(CrMoTaW)_{0.25}O₃. Additionally or alternatively, in some embodiments, the spin-orbit coupling stack 116 may include, e.g., niobium. The ratio of the various cations in a high-entropy perovskite may be any suitable value, such as 1:1 for each cation up to, e.g., 10:1 for any two cations (by number of atoms). In other embodiments, the spin-orbit coupling stack 116 may be or include, e.g., bismuth and silver, platinum, topological insulators, oxide such as SrIrO₃, or two-dimensional materials.

The use of perovskites and/or high-energy perovskites in some or all of the layers of the MESO logic structure 100 may provide several advantages. The reduction or elimination of oxide/metal interfaces may reduce oxygen vacancy trapping. Some or all of the various layers, such as the magnetoelectric layer 106, the ferromagnetic layers 108, 112, and the spin-orbit coupling stack 116 may be compatible with each other for epitaxial growth, allowing for high-quality layers with atomically-sharp interfaces to be deposited relatively easily. Some or all of the various layers may be lattice matched to each other. As used herein, two layers are lattice matching if one layer has a lattice constant that is within 1% of the lattice constant of the other layer. In other embodiments, some or all of the various layers may have a lattice mismatch with adjacent layers that is lower, such as less than 0.1% or less than 0.01% mismatch.

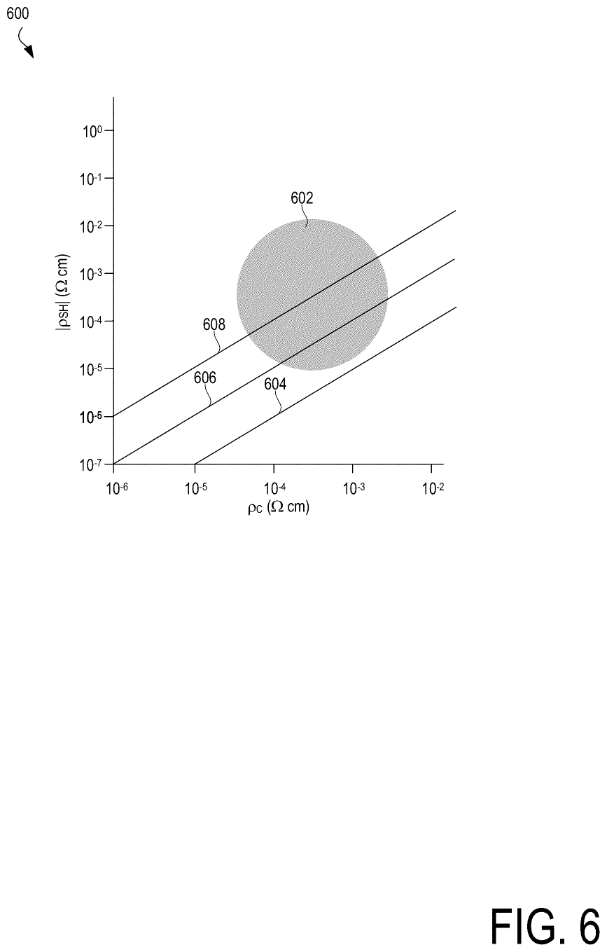

The use of high-entropy perovskites allows for both intrinsic and extrinsic contribution to the inverse spin Hall effect. The use of high-entropy perovskites for the spin-orbit coupling stack 116 also allows for versability through tunability, as the wide range of possible combinations allows for a wide range of possible performance metrics. For example, FIG. 6 shows a region 602 for expected values of possible performance for high-entropy perovskites. FIG. 6 shows spin Hall resistivity (defined as the product of the spin Hall angle and the normal charge resistivity) as a function of resistivity. Line 604 corresponds to a spin Hall angle of 0.01, line 606 corresponds to a spin Hall angle of 0.1, and line 608 corresponds to a spin Hall angle of 1.0.

It should be appreciated that FIGS. 1-5 show a MESO logic structure 100 with differential inputs and outputs. However, it should be appreciated that a MESO logic structure 100 with single-ended inputs and/or outputs are envisioned as well.

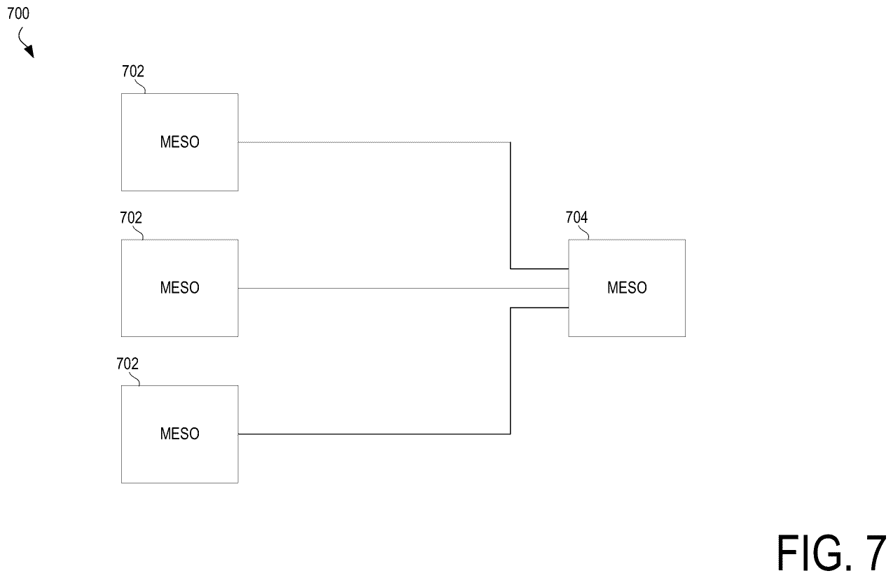

It should be appreciated that the MESO logic structure 100 may form part of one or more logic gates that are or can be combined to form universal logic gates. For example, in one embodiment, as shown in FIG. 7, a majority gate 700 may be formed by connecting the output electrodes 118, 120 of three MESO logic structures 702 together and to the input electrodes 102, 104 of another MESO logic structure 704. The voltage on the input electrodes 102, 104 of the MESO logic structure 704 will be positive or negative based on whether the majority voltages on the output electrodes 118, 120 of the MESO logic structures 702 are positive or negative. The overall output of the final MESO logic structure 704 will correspond to the majority output of the three input MESO logic structures 702. As another example, the output electrodes 118, 120 of each of three MESO logic structures 702 may be placed across the magnetoelectric layer 106 of a majority gate MESO logic structure 100 without connecting the output electrodes 118, 120 of the three MESO logic structures 702 together. The overall polarization of the magnetoelectric layer 106 of the MESO logic structure 704 will correspond to the majority input voltages across it, leading to the output of the majority gate 700 to be the majority of the input.

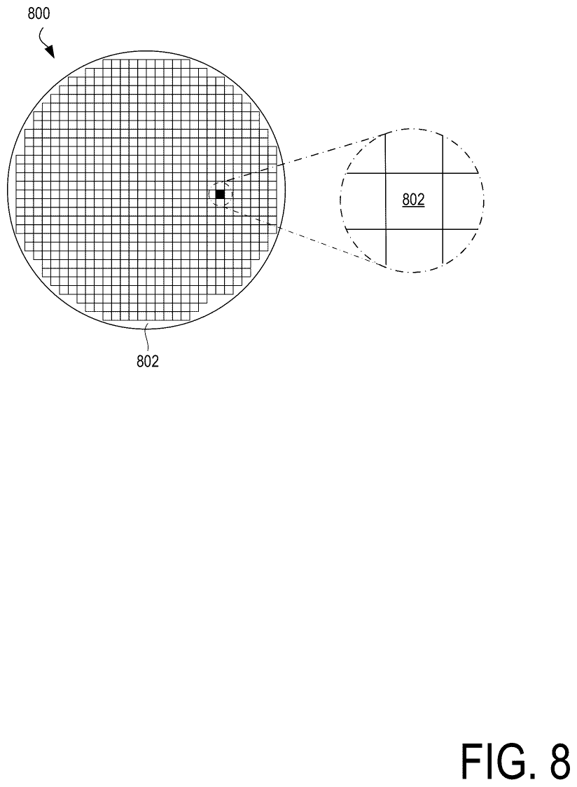

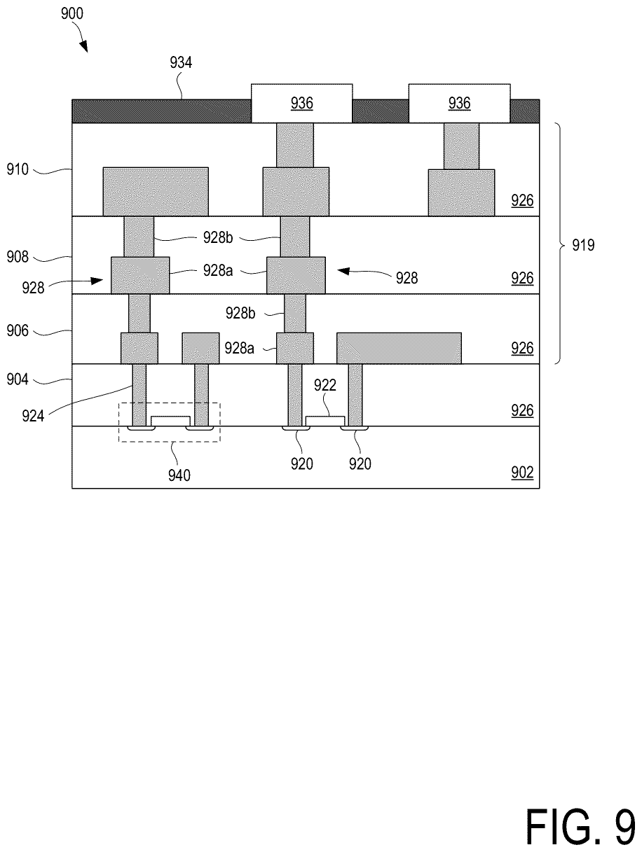

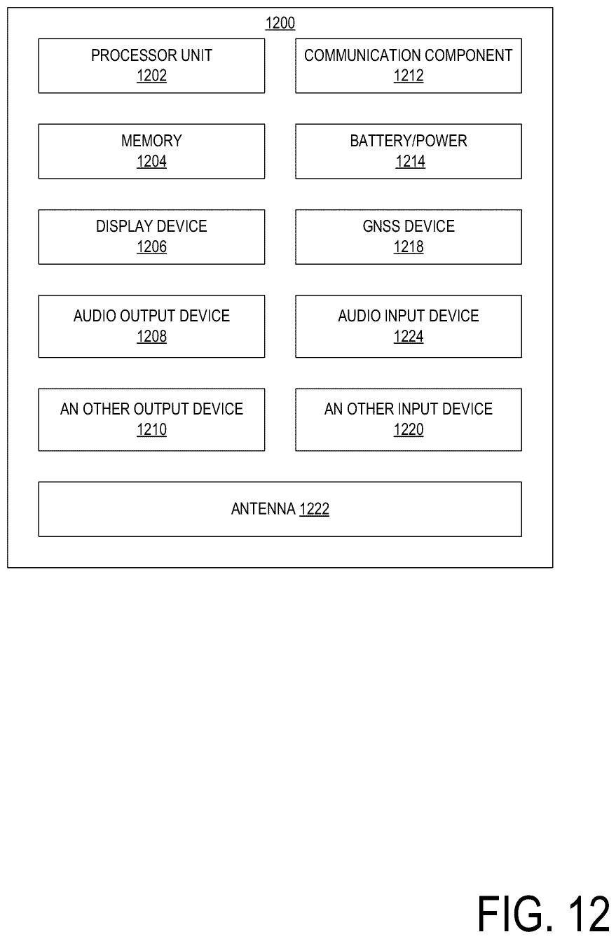

FIG. 8 is a top view of a wafer 800 and dies 802 that may include any of the MESO logic structures 100 disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may include any of the MESO logic structures 100 disclosed herein. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. Various ones of the MESO logic structures 100 disclosed herein may be manufactured using a die-to-wafer assembly technique in which some dies are attached to a wafer 800 that include others of the dies, and the wafer 800 is subsequently singulated.

FIG. 9 is a cross-sectional side view of an integrated circuit device 900 that may include any of the MESO logic structures 100 disclosed herein. One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

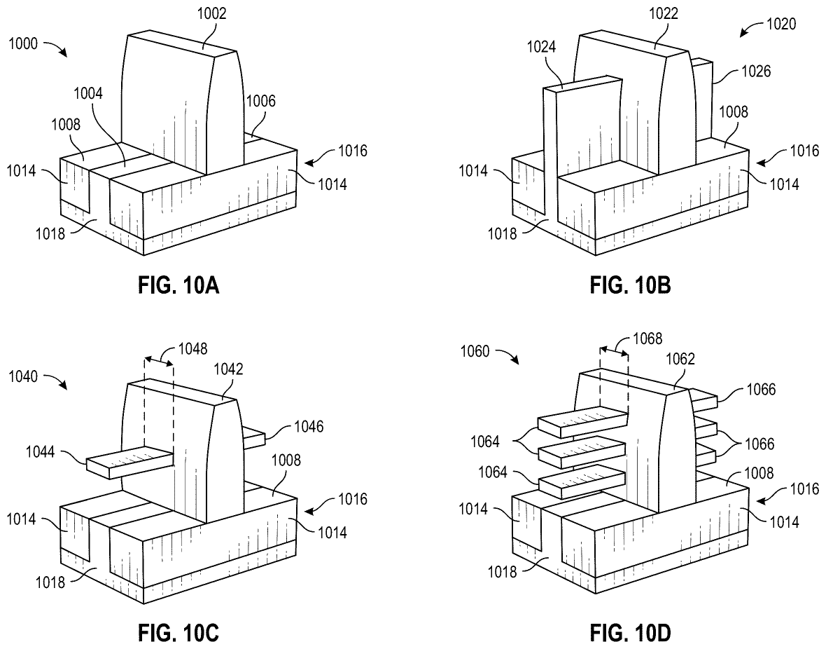

FIGS. 10A-10D are simplified perspective views of example planar, FinFET, gate-all-around, and stacked gate-all-around transistors. The transistors illustrated in FIGS. 10A-10D are formed on a substrate 1016 having a surface 1008. Isolation regions 1014 separate the source and drain regions of the transistors from other transistors and from a bulk region 1018 of the substrate 1016.

FIG. 10A is a perspective view of an example planar transistor 1000 comprising a gate 1002 that controls current flow between a source region 1004 and a drain region 1006. The transistor 1000 is planar in that the source region 1004 and the drain region 1006 are planar with respect to the substrate surface 1008.

FIG. 10B is a perspective view of an example FinFET transistor 1020 comprising a gate 1022 that controls current flow between a source region 1024 and a drain region 1026. The transistor 1020 is non-planar in that the source region 1024 and the drain region 1026 comprise “fins” that extend upwards from the substrate surface 1028. As the gate 1022 encompasses three sides of the semiconductor fin that extends from the source region 1024 to the drain region 1026, the transistor 1020 can be considered a tri-gate transistor. FIG. 10B illustrates one S/D fin extending through the gate 1022, but multiple S/D fins can extend through the gate of a FinFET transistor.

FIG. 10C is a perspective view of a gate-all-around (GAA) transistor 1040 comprising a gate 1042 that controls current flow between a source region 1044 and a drain region 1046. The transistor 1040 is non-planar in that the source region 1044 and the drain region 1046 are elevated from the substrate surface 1028.

FIG. 10D is a perspective view of a GAA transistor 1060 comprising a gate 1062 that controls current flow between multiple elevated source regions 1064 and multiple elevated drain regions 1066. The transistor 1060 is a stacked GAA transistor as the gate controls the flow of current between multiple elevated S/D regions stacked on top of each other. The transistors 1040 and 1060 are considered gate-all-around transistors as the gates encompass all sides of the semiconductor portions that extends from the source regions to the drain regions. The transistors 1040 and 1060 can alternatively be referred to as nanowire, nanosheet, or nanoribbon transistors depending on the width (e.g., widths 1048 and 1068 of transistors 1040 and 1060, respectively) of the semiconductor portions extending through the gate.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

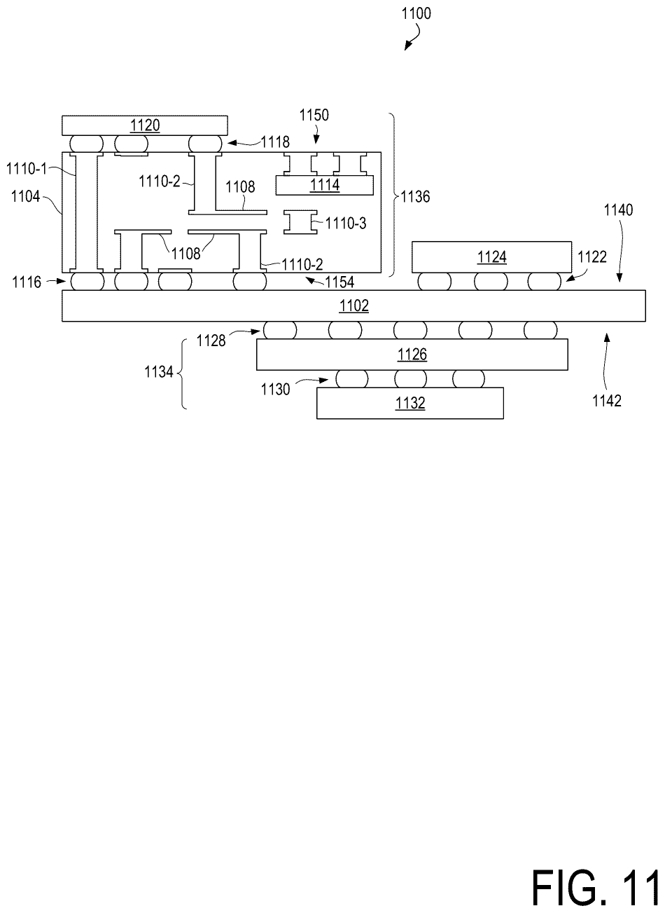

FIG. 11 is a cross-sectional side view of an integrated circuit device assembly 1100 that may include any of the MESO logic structures 100 disclosed herein. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel@ embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the MESO logic structures 100 disclosed herein. For example, any suitable ones of the components of the electrical device 1200 may include one or more of the integrated circuit device assemblies 1100, integrated circuit components 1120, integrated circuit devices 900, or integrated circuit dies 802 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (Li), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include an other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an other input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

### EXAMPLES

Illustrative examples of the technologies disclosed herein are provided below. An embodiment of the technologies may include any one or more, and any combination of, the examples described below.

Example 1 includes a die comprising a magnetoelectric layer; a ferromagnetic layer; one or more input electrodes, wherein the one or more input electrodes, when a voltage is applied, induce a polarization in the magnetoelectric layer and the ferromagnetic layer based on the applied voltage; a spin-orbit coupling layer; and one or more output electrodes, wherein, when a current is applied through the ferromagnetic layer and the spin-orbit coupling layer, a voltage is induced on the one or more output electrodes, wherein the ferromagnetic layer is a first perovskite, wherein the spin-orbit coupling layer is a second perovskite.

Example 2 includes the subject matter of Example 1, and wherein the spin-orbit coupling layer is a high-entropy perovskite.

Example 3 includes the subject matter of any of Examples 1 and 2, and wherein the spin-orbit coupling layer comprises chromium, niobium, molybdenum, tungsten, and oxygen.

Example 4 includes the subject matter of any of Examples 1-3, and wherein the spin-orbit coupling layer comprises approximately equal amounts of chromium, niobium, molybdenum, and tungsten, by number of atoms.

Example 5 includes the subject matter of any of Examples 1-4, and wherein the spin-orbit coupling layer comprises strontium, chromium, molybdenum, tantalum, tungsten, and oxygen.

Example 6 includes the subject matter of any of Examples 1-5, and wherein the spin-orbit coupling layer comprises approximately equal amounts of chromium, molybdenum, tantalum, tungsten, by number of atoms.

Example 7 includes the subject matter of any of Examples 1-6, and wherein the ferromagnetic layer comprises strontium, calcium, ruthenium, and oxygen.

Example 8 includes the subject matter of any of Examples 1-7, and wherein the ferromagnetic layer comprises strontium, iron, molybdenum, and oxygen.

Example 9 includes the subject matter of any of Examples 1-8, and wherein the magnetoelectric layer is a third perovskite.

Example 10 includes the subject matter of any of Examples 1-9, and wherein the magnetoelectric layer comprises bismuth, iron, and lanthanum.

Example 11 includes the subject matter of any of Examples 1-10, and wherein the magnetoelectric layer is lattice matched to the ferromagnetic layer, wherein the ferromagnetic layer is lattice matched to the spin-orbit coupling layer.

Example 12 includes the subject matter of any of Examples 1-11, and wherein the spin-orbit coupling layer is adjacent the ferromagnetic layer.

Example 13 includes the subject matter of any of Examples 1-12, and further including a spin injection layer between the spin-orbit coupling layer and the ferromagnetic layer.

Example 14 includes the subject matter of any of Examples 1-13, and further including a majority gate, wherein the majority gate comprises the magnetoelectric layer, the ferromagnetic layer, the one or more input electrodes, the spin-orbit coupling layer, and the one or more output electrodes.

Example 15 includes a processor comprising the die of claim 1.

Example 16 includes a die comprising a magnetoelectric layer; a ferromagnetic layer; one or more input electrodes, wherein the one or more input electrodes, when a voltage is applied, induces a polarization in the magnetoelectric layer and the ferromagnetic layer based on the applied voltage; a spin-orbit coupling layer; and one or more output electrodes, wherein, when a current is applied through the ferromagnetic layer and the spin-orbit coupling layer, a voltage is induced on the one or more output electrodes, wherein the spin-orbit coupling layer is a high entropy oxide.

Example 17 includes the subject matter of Example 16, and wherein the spin-orbit coupling layer is a high-entropy perovskite.

Example 18 includes the subject matter of any of Examples 16 and 17, and wherein the spin-orbit coupling layer comprises chromium, niobium, molybdenum, tungsten, and oxygen.

Example 19 includes the subject matter of any of Examples 16-18, and wherein the spin-orbit coupling layer comprises approximately equal amounts of chromium, niobium, molybdenum, and tungsten, by number of atoms.

Example 20 includes the subject matter of any of Examples 16-19, and wherein the spin-orbit coupling layer comprises strontium, chromium, molybdenum, tantalum, tungsten, and oxygen.

Example 21 includes the subject matter of any of Examples 16-20, and wherein the spin-orbit coupling layer comprises approximately equal amounts of chromium, molybdenum, tantalum, tungsten, by number of atoms.

Example 22 includes the subject matter of any of Examples 16-21, and wherein the ferromagnetic layer comprises strontium, calcium, ruthenium, and oxygen.

Example 23 includes the subject matter of any of Examples 16-22, and wherein the ferromagnetic layer comprises strontium, iron, molybdenum, and oxygen.

Example 24 includes the subject matter of any of Examples 16-23, and wherein the magnetoelectric layer is a third perovskite.

Example 25 includes the subject matter of any of Examples 16-24, and wherein the magnetoelectric layer comprises bismuth, iron, and lanthanum.

Example 26 includes the subject matter of any of Examples 16-25, and wherein the magnetoelectric layer is lattice matched to the ferromagnetic layer, wherein the ferromagnetic layer is lattice matched to the spin-orbit coupling layer.

Example 27 includes the subject matter of any of Examples 16-26, and wherein the spin-orbit coupling layer is adjacent the ferromagnetic layer.

Example 28 includes the subject matter of any of Examples 16-27, and further including a spin injection layer between the spin-orbit coupling layer and the ferromagnetic layer.

Example 29 includes the subject matter of any of Examples 16-28, and further including a majority gate, wherein the majority gate comprises the magnetoelectric layer, the ferromagnetic layer, the one or more input electrodes, the spin-orbit coupling layer, and the one or more output electrodes.

Example 30 includes a processor comprising the die of claim 16.

Example 31 includes a die comprising a spin-orbit coupling layer; and a ferromagnetic layer located on the spin-orbit coupling layer; and wherein the ferromagnetic layer is lattice matched to the spin-orbit coupling layer.

Example 32 includes the subject matter of Example 31, and wherein the spin-orbit coupling layer is a high-entropy perovskite.

Example 33 includes the subject matter of any of Examples 31 and 32, and wherein the spin-orbit coupling layer comprises chromium, niobium, molybdenum, tungsten, and oxygen.

Example 34 includes the subject matter of any of Examples 31-33, and wherein the spin-orbit coupling layer comprises approximately equal amounts of chromium, niobium, molybdenum, and tungsten, by number of atoms.

Example 35 includes the subject matter of any of Examples 31-34, and wherein the spin-orbit coupling layer comprises strontium, chromium, molybdenum, tantalum, tungsten, and oxygen.

Example 36 includes the subject matter of any of Examples 31-35, and wherein the spin-orbit coupling layer comprises approximately equal amounts of chromium, molybdenum, tantalum, tungsten, by number of atoms.

Example 37 includes the subject matter of any of Examples 31-36, and wherein the ferromagnetic layer comprises strontium, calcium, ruthenium, and oxygen.

Example 38 includes the subject matter of any of Examples 31-37, and wherein the ferromagnetic layer comprises strontium, iron, molybdenum, and oxygen.

Example 39 includes the subject matter of any of Examples 31-38, and further including a magnetoelectric layer adjacent the ferromagnetic layer, wherein the magnetoelectric layer is lattice matched to the ferromagnetic layer.

Example 40 includes the subject matter of any of Examples 31-39, and wherein the magnetoelectric layer comprises bismuth, iron, and lanthanum.

Example 41 includes the subject matter of any of Examples 31-40, and wherein the spin-orbit coupling layer is adjacent the ferromagnetic layer.

Example 42 includes the subject matter of any of Examples 31-41, and further including a spin injection layer between the spin-orbit coupling layer and the ferromagnetic layer.

Example 43 includes the subject matter of any of Examples 31-42, and further including a majority gate, wherein the majority gate comprises the ferromagnetic layer and the spin-orbit coupling layer.

Example 44 includes a processor comprising the die of claim 31.

1. A die comprising:
a magnetoelectric layer;
a ferromagnetic layer;
one or more input electrodes, wherein the one or more input electrodes, when a voltage is applied, induce a polarization in the magnetoelectric layer and the ferromagnetic layer based on the applied voltage;
a spin-orbit coupling layer; and
one or more output electrodes, wherein, when a current is applied through the ferromagnetic layer and the spin-orbit coupling layer, a voltage is induced on the one or more output electrodes,
wherein the ferromagnetic layer is a first perovskite, wherein the spin-orbit coupling layer is a second perovskite.

2. The die of claim 1, wherein the spin-orbit coupling layer is a high-entropy perovskite.

3. The die of claim 1, wherein the spin-orbit coupling layer comprises chromium, niobium, molybdenum, tungsten, and oxygen.

4. The die of claim 3, wherein the spin-orbit coupling layer comprises approximately equal amounts of chromium, niobium, molybdenum, and tungsten, by number of atoms.

5. The die of claim 1, wherein the spin-orbit coupling layer comprises strontium, chromium, molybdenum, tantalum, tungsten, and oxygen.

6. The die of claim 5, wherein the spin-orbit coupling layer comprises approximately equal amounts of chromium, molybdenum, tantalum, tungsten, by number of atoms.

7. The die of claim 1, wherein the ferromagnetic layer comprises strontium, calcium, ruthenium, and oxygen.

8. The die of claim 1, wherein the ferromagnetic layer comprises strontium, iron, molybdenum, and oxygen.

9. The die of claim 1, wherein the magnetoelectric layer is a third perovskite.

10. The die of claim 9, wherein the magnetoelectric layer comprises bismuth, iron, and lanthanum.

11. The die of claim 1, wherein the magnetoelectric layer is lattice matched to the ferromagnetic layer, wherein the ferromagnetic layer is lattice matched to the spin-orbit coupling layer.

12. The die of claim 1, further comprising a majority gate, wherein the majority gate comprises the magnetoelectric layer, the ferromagnetic layer, the one or more input electrodes, the spin-orbit coupling layer, and the one or more output electrodes.

13. A processor comprising the die of claim 1.

14. A die comprising:
a magnetoelectric layer;
a ferromagnetic layer;
one or more input electrodes, wherein the one or more input electrodes, when a voltage is applied, induces a polarization in the magnetoelectric layer and the ferromagnetic layer based on the applied voltage;
a spin-orbit coupling layer; and
one or more output electrodes, wherein, when a current is applied through the ferromagnetic layer and the spin-orbit coupling layer, a voltage is induced on the one or more output electrodes,
wherein the spin-orbit coupling layer is a high entropy oxide.

15. The die of claim 14, wherein the spin-orbit coupling layer is a high-entropy perovskite.

16. The die of claim 14, wherein the spin-orbit coupling layer comprises chromium, niobium, molybdenum, tungsten, and oxygen.

17. A die comprising:
a spin-orbit coupling layer; and
a ferromagnetic layer located on the spin-orbit coupling layer; and
wherein the ferromagnetic layer is lattice matched to the spin-orbit coupling layer.

18. The die of claim 17, wherein the spin-orbit coupling layer is a high-entropy perovskite.

19. The die of claim 17, wherein the spin-orbit coupling layer comprises strontium, chromium, molybdenum, tantalum, tungsten, and oxygen.

20. The die of claim 17, wherein the ferromagnetic layer comprises strontium, iron, molybdenum, and oxygen.
